(19) United States
(12) Patent Application Publication
(10) Pub. No.: US 2006/0185895 A1
(43) Pub. Date: Aug. 24, 2006

(54) Universal pattern of contact pads for semiconductor reflow interconnections

(76) Inventor: Navinchandra Kalidas, Houston, TX (US)

Correspondence Address: TEXAS INSTRUMENTS INCORPORATED, P O BOX 655474, M/S 3999, DALLAS, TX, 75265, US

(21) Appl. No.: 11/065,251

(22) Filed: Feb. 24, 2005

(51) Int. Cl. H05K 1/11

(52) U.S. Cl. 174/261

(57) ABSTRACT

An insulating substrate comprises an orderly and repetitive arrangement of a plurality of metal pads (320, 321) of about the same size interconnected by conductive traces (330), wherein these traces form parallel equidistant rows. The plurality of pads is divided in sub-arrays (380, 381) of equal numbers of pads. The pads in each sub-array are positioned so that the corresponding pad of each following row is located at a predetermined angle (370) relative to the corresponding pad of the preceding row, and the angle is selected for minimizing the pitch of the traces, center to center, and maximizing the pad density. Further, the respective traces of each sub-array are connected so that the pads of one sub-array are positioned as the mirror image of the pads of the adjacent sub-arrays.

### FIELD OF THE INVENTION

The present invention is related in general to the field of electrical systems and semiconductor devices and more specifically to substrates in semiconductor assembly having a universal pattern of the contact pads for reflow interconnections.

### DESCRIPTION OF THE RELATED ART

When semiconductor chips are assembled on metallic leadframes, the bond pads for connecting the chip inputs/outputs to the leadframe segments are typically arranged around the chip periphery in locations, which allow a more or less uniform distribution of the segments. Engineers, which had to design leadframes and leadframe segments, have spent considerable effort to reconcile the needs for bond pad numbers and pitch, center-to-center or staggering, with the limitations in segment pitch, center-to-center, the aspect ratios of segment width and leadframe thickness, and the wire bonding capabilities (ball size, wire span length and shape, etc.). As a result, the segment distribution permits frequently the assembly of various chip sizes on one type of leadframe.

In contrast, semiconductor chips which are to be flip-assembled using metal reflow (solder) connections, are no longer technically constrained with regard to the location of the chip input/outputs pads, but are usually free to use any location of the chip area. Consequently, the pad patterns for the reflow members are usually unique for each chip type.

Flipping chips onto insulating substrates or similar interface media requires that the pattern of the metallic contact pads on the substrate follows the chip pad pattern as an exact mirror image. Since the chips of each device type tend to be unique, the substrates intended for those devices have to be designed with their unique patterns of contact pads—a cumbersome and expensive consequence.

### SUMMARY OF THE INVENTION

A need has therefore arisen to develop concepts for universal bump pad patterns for integrated circuit chips and their associated substrates in flip-chip application. These concepts should demonstrate their viability for certain device families. The concepts are expected to be based on mathematical rules for maximum packing density and minimum spacing, while retaining good engineering practices for designs, which are robust in view of the fabrication processes employed.

One embodiment of the present invention provides an insulating substrate, which has an orderly and repetitive arrangement of metal pads interconnected by parallel conductive traces, each pad having about the same size. The pads and traces are arranged to achieve minimum spacing between the traces and maximum pad density. For certain embodiments, the pad arrangement is a rectangular array. For other embodiments, the pad arrangement comprises a plurality of rectangular arrays, wherein each array preferably forms an angle with an adjacent array.

Another embodiment of the invention comprises an insulating substrate, in which an orderly and repetitive arrangement of metal pads of about the same size is interconnected by conductive traces. These traces form parallel equidistant rows, and the pads are positioned so that the corresponding pad of each following row is located at a predetermined acute angle relative to the corresponding pad of the preceding row. The angle is selected for minimizing the pitch of the traces, center to center, and maximizing the pad density.

Another embodiment of the invention is represented by an insulating substrate, which comprises an orderly and repetitive arrangement of a plurality of metal pads of about the same size interconnected by conductive traces, wherein these traces form parallel equidistant rows. The plurality of pads is divided in sub-arrays of equal numbers of pads. The pads in each sub-array are positioned so that the corresponding pad of each following row is located at a predetermined angle relative to the corresponding pad of the preceding row, and the angle is selected for minimizing the pitch of the traces, center to center, and maximizing the pad density. Further, the respective traces of each sub-array are connected so that the pads of one sub-array are positioned as the mirror image of the pads of the adjacent sub-arrays.

Another embodiment of the invention is an apparatus comprising an insulating substrate, which has first and second surfaces and a plurality of metal-filled vias extending from the first to the second surface. The first surface has contact pads of about the same size, and the second surface has contact pad of about the same size. A selected plurality of the pads on the first and second surfaces is connected to one of the vias, respectively. The contact pads on the first surface are equidistantly arrayed in parallel rows, the pads in each row interconnected by conducting traces and positioned so that the corresponding pad of each following row is located at a predetermined angle relative to the respective pad of the preceding row. The angle is selected for minimizing the pitch of the traces, center-to-center, and maximizing the pad density. The apparatus is suitable for an integrated circuit assembly so that the pads on the first substrate surface are operable as signal input/output terminals by being arranged in number and position to match the corresponding signal input/output pads of the integrated circuit.

It is a technical advantage of the invention that the trace pitch can be scaled according the number and the position of the integrated circuit pads.

It is another technical advantage of the invention that the substrate design is flexible and can easily be expanded to new chip sized in the same device family.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1A shows a schematic top view of a semiconductor chip intended for wire bonding.

FIG. 1B shows a detailed top view of a portion of the chip in FIG. 1A, the portion depicting bond pads distributed according to known technology.

FIG. 2A shows a schematic top view of a semiconductor chip intended for bumps and flip assembly.

FIG. 2B shows a detailed top view of a portion of the chip in FIG. 2A, the portion depicting bump pads and interconnections distributed according to known technology.

FIG. 3A illustrates a schematic top view of a family of semiconductor chips of consecutive sizes intended for bumps and flip assembly.

FIG. 3B illustrates a schematic top view of a portion of the chips of consecutive sizes in FIG. 2A, that portion depicting bump assembly pads and interconnections in orderly and repetitive arrangement according to an embodiment of the invention.

### DETAILED DESCRIPTION OF THE PREFERRED EMBODIMENTS

The impact of the present invention can be most easily appreciated by highlighting the shortcomings of the known approaches to arrange contact pads and interconnections on substrates, when semiconductor chips of various sizes need to be assembled.

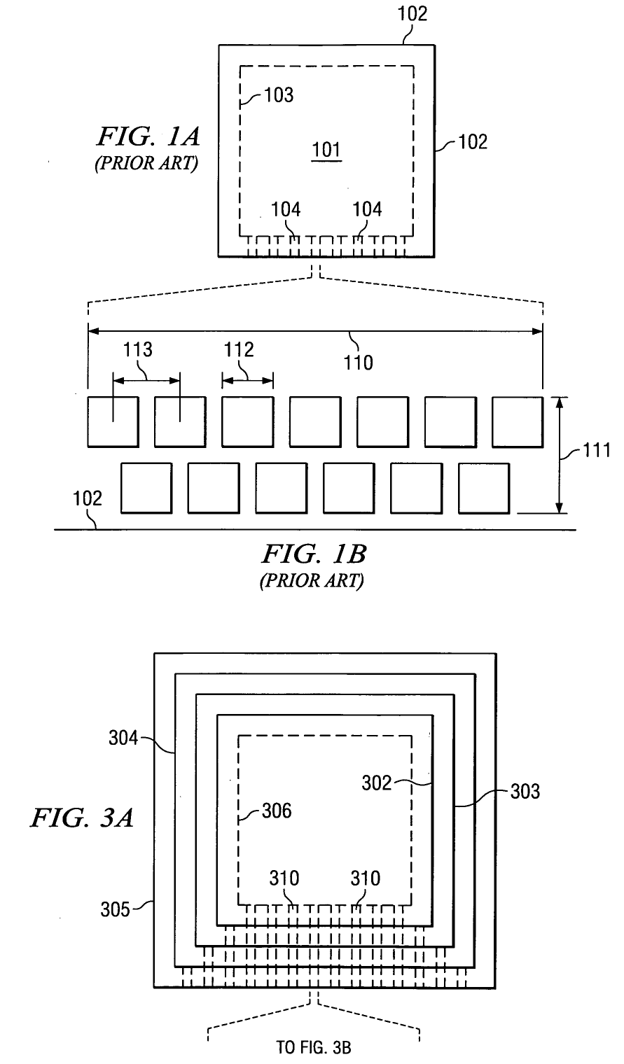

FIG. 1A is a schematic top view of a chip 101 in known technology. In the example shown, the chip has a square-shaped outline with a side 102; the side length, for instance, may be 8 mm. The dashed lines 103 delineate the peripheral chip areas, which are reserved for bond pads in those examples, where conventional wire ball bonding is to be used for interconnecting the chip to external parts. As is well known in wire bond technology, the technical restrictions of wire sagging and wire sweep require that the wire lengths have to be kept as short as possible, and the bond pads, consequently, have to be close to the chip periphery. Within this peripheral area, a plurality of bond pads may be grouped together and designated 104; several groups are illustrated on FIG. 1A.

One of these groups 104 is magnified in FIG. 1B. The group consists of two rows of bond pads in staggered arrangement. The overall length of the group is designated 110; in the example of FIG. 1B, it measures about 0.45 mm. The depth is designated 111 and measures about 0.15 mm. The side length of an individual bond pad is designated 112 and measures about 0.05 mm; the pad pitch center-to-center is designated 113 and measures approximately 0.65 mm. Based on the staggered arrangement of two rows, about 25 bond pads can be accommodated within 1 mm of chip periphery.

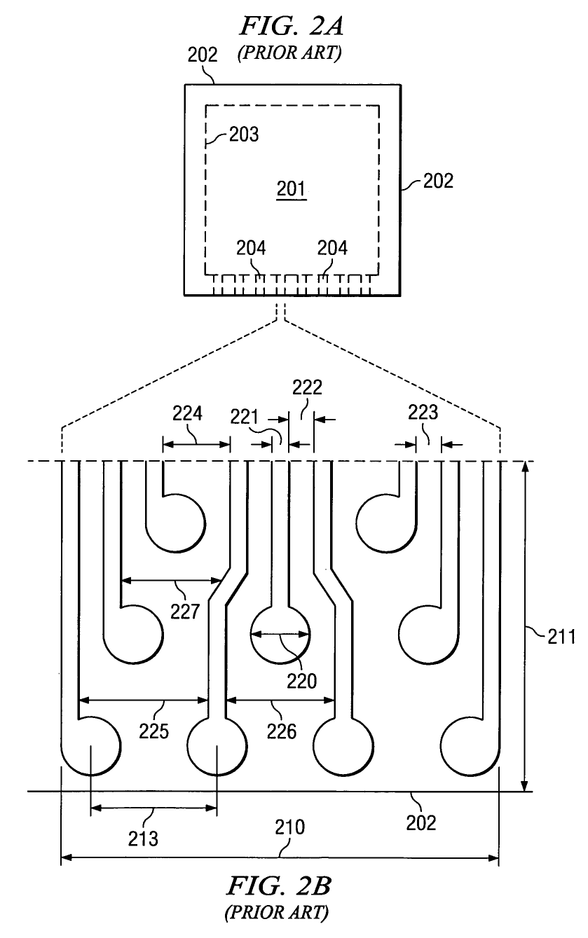

The conventional wire bond situation of FIGS. 1A and 1B is compared with the conventional flip-chip situation in FIGS. 2A and 2B. FIG. 2A is a schematic top view of a chip 201, wherein the chip has a square-shaped outline with a side 202; the side length, for instance, may be 8 mm. The dashed lines 203 delineate the peripheral chip areas, which are reserved for contact pads employed for the bumps or balls needed on interconnecting the chip to external parts. Within this peripheral area, a plurality of contact pads may be grouped together and designated 204; several groups are illustrated in the example of FIG. 2A.

One of these groups 204 is magnified in FIG. 2B. The overall length of the group is designated 210 and assumed to be 0.45 mm, the same length as the length 110 for the group of bond pads in FIG. 1B. The depth is designated 211 and measures about 0.30 mm. This is twice the depth compared to the depth 111 required for the staggered rows of bond pads in FIG. 1B. The expansion of bump contact pads is feasible, since bumps are in principle free to be located over the whole chip area, because they are not constrained by wire-spanning limitations.

FIG. 2B demonstrates that the contact pads need to be arrayed in rows of various pitches, center to center of bump pads. The smallest pitch is designated 213; it belongs to the pads nearest the chip periphery 202 and has, in this example, a dimension of about 0.15 mm. The smallest diagonal bump pad pitch is (0.8×0.15)=0.12 mm.

The bump pads in FIG. 2B are assumed to have a diameter 220 of about 0.075 mm. The position of the bump pads relative to each other is variable within a considerable margin and their selection left to the discretion of the chip designer. Furthermore, as FIG. 2B shows, a considerable amount of chip area is consumed by the bump interconnection traces 221. The traces have, in this example, a width of about 0.018 mm, with a smallest separation 222 of about 0.032 mm, resulting in a smallest trace pitch center-to-center of 0.05 mm. With these layout rules of FIGS. 2A and 2B and extrapolated to 1 mm, only 17 bump pads can be accommodated, where 25 bond pads in staggered arrangement could be accommodated in the example of FIGS. 1A and 1B. The ratio of 68% of bump pads versus bond pads is in disfavor of bump pads on known technology.

FIG. 2B shows that the separation of traces 221 is not constant. For example, while distance 222 is the smallest, distance 223 is slightly larger, yet distances 224, 225, and 226 are considerably larger, and distance 227 is variable.

It should be stressed that in flip-chip technology, a top view image of the substrate bump pads has to be the mirror image of the chip bump pads. Consequently, the schematic top view of FIG. 2B also illustrates the bump, pad arrangement of the substrate intended for assembling the chip.

Due to the various distances between connecting traces described above, and due to the unregulated positioning of the bump pads, bump pads can be located differently from chip to chip, and, consequently, the mirror-image substrates can vary from chip to chip—a cumbersome and expensive task for the fabrication of these substrates.

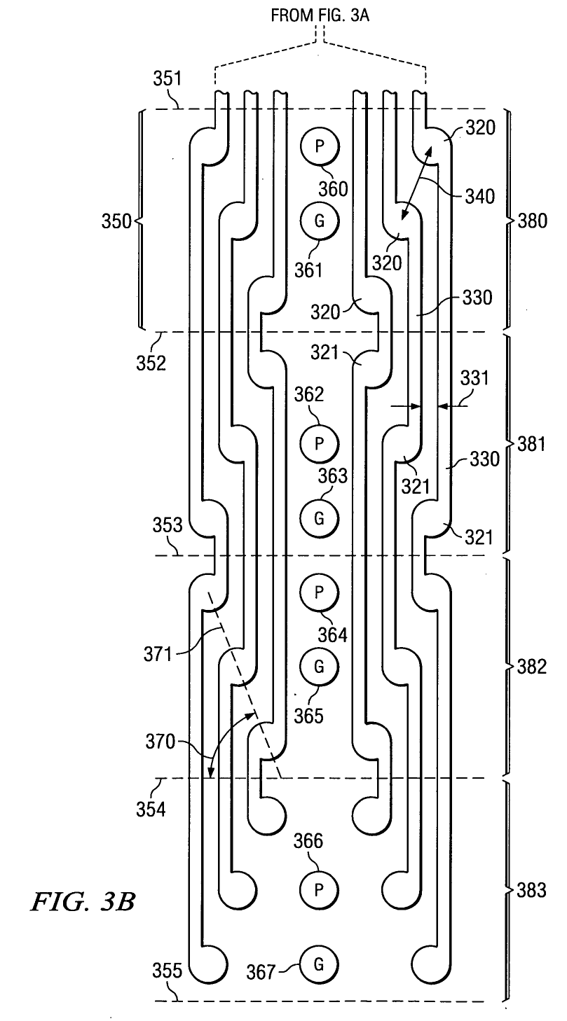

FIG. 3A is a schematic top view of a family of semiconductor chips of consecutive sizes. In the example shown, the chips have square-shaped outlines. The smallest chip has side 302, which may have a length of 8 mm. The next larger chip has side 303 with length of 9 mm; the next larger chip has side 304 with length of 10 mm; and the largest chip has side 305 with length 11 mm.

Dashed lines 306 delineate the peripheral chip areas, which are reserved for contact pads employed for the bumps or balls needed for interconnecting the chip to external parts. Within this peripheral area, a plurality of contact pads may be grouped together and designated 310; several groups are illustrated on FIG. 3A.

One of these groups 310 is magnified in the schematic top view of FIG. 3B. As stated earlier, the distribution of contact pads for bumps on a chip is mirror-imaged on the substrate intended for assembly of the chip. FIG. 3B is thus also a top view of the substrate provided for assembling the semiconductor chip. Substrates are typically made of insulating material including polyimide, epoxy, and related polymers, sometimes fortified by glass fibers, and commercially available under names such as FR-4 and FR-5.

The schematic top view of the insulating substrate in FIG. 3B shows an orderly and repetitive arrangement of metal pads 320 interconnected by parallel conductive traces 330, each pad 320 having about the same size. These pads and traces are arranged to achieve minimum spacing 331 between said traces and maximum pad density. The spacing 331 is constant throughout the arrangement, and the traces are always parallel to each other.

The pitch between adjacent contact pads, center-to-center, is constant and designated 340 in FIG. 3B. As illustrated in FIG. 3B, a certain number of pads (the number is 6 in FIG. 3B) is arranged in an orderly rectangular array, designated 350. Since these pads are preferably signal input/output pads, there may be a certain number of additional pads for power and ground connections interspersed at pre-determined locations within this rectangular array of signal pads. One such pad for power is designated 360 in FIG. 3B, and one such ground pad is designated 361.

The overall arrangement of pads in FIG. 3B comprises a plurality of rectangular arrays 350; as illustrated in FIG. 3B, there are 4 rectangular arrays interconnected to form the overall arrangement. The demarcation lines defining the arrays are 351, 352, 353, 354, and 355 may coincide with the chip side lines 306, etc., of FIG. 3A. Demarcation line 355 coincides then with the 11 mm chip side 305. Each array of the plurality of arrays forms an angle with the adjacent arrays. The angle (for example, 370) is relative to the confining line (for example, 352) of an array and is acute.

The concept of contact pad layout for a given number of pads on an insulating substrate, as illustrated in FIG. 3B, can thus be described as an orderly and repetitive arrangement of metal pads of about the same size interconnected by conductive traces, wherein these traces are forming parallel equidistant rows. The contact pads are positioned so that the corresponding pad of each following row is located at a predetermined acute angle relative to the corresponding pad of the preceding row. This angle is selected for minimizing the pitch of the traces, center to center, and maximizing the pad density. While this is the preferred concept for signal input/output pads, a given number of power and ground pads may be interspersed between the signal pads, utilizing any available leftover area.

When a certain plurality of metal pads of about the same size on an insulating substrate or on a chip, which can be interconnected by conductive traces in parallel, equidistant rows, have to be arranged for best utilization of the available surface area, a preferred way of progression is as follows:

Divide the plurality of pads in sub-arrays of equal number of pads; sub-arrays can be added or subtracted;

interconnect the pads by conductive traces, which form parallel equidistant rows;

repeat these steps interactively to create an orderly and repetitive arrangement;

position the pads in each sub-array so that the corresponding pad of each following row is located at a predetermined angle relative to the corresponding pad of the preceding row; the angle selected for minimizing the pitch of the traces, center to center, and maximizing the pad density; and

connect the respective traces of each sub-array so that the pads of one sub-array are positioned as the mirror image of the pads of the adjacent sub-arrays.

An array of pads of about equal size, which has been constructed in such manner, is illustrated in FIG. 3B. The total number of 32 pads of about equal size has been divided into 4 sub-arrays having the equal number of 8 pads each. The sub-arrays are designated 380, 381, 382, and 383. Within each sub-array, the power and ground pads are separated; examples are power pads 360, 362, 364, and 366, and ground pads 361, 363, 365, and 367. The signal pads within each sub-array are arranged so that one pad of each sub-array (for instance a pad 320 in sub-array 380) can be interconnected with a corresponding pad in the adjacent sub-array (for instance a pad 321 in subarray-381) by a conductive trace (for instance, trace 330). The traces are arranged to be parallel and equidistant to each other (for instance, distance 331). The position of corresponding pads in adjacent sub-arrays is then modified relative to each other so that the pitch of the connecting traces is minimized and, simultaneously, the density of the connected pads is maximized.

As a result, the pads of neighboring traces within each sub-array become linearly aligned (notice, for instance, line 371 through the center of neighboring pads), and this line forms an acute angle with the confining line of the sub-array (for instance, angle 370 between lines 371 and 352). As a consequence, when one sub-array is folded into the adjacent sub-array (for instance, sub-array 380 into sub-array 381) along the demarcation line (for instance, line 352) as rotation axis, the pads of one sub-array appear positioned as mirror images of the pads of the adjacent sub-array. In FIG. 3B, the mirror image relationship is repeated for the sub-arrays at each demarcation line (352, 252, 354). Consequently, sub-arrays can be added or subtracted to satisfy an increase or decrease of number of pads, for example due to increase or decrease of chip size. The high density and flexible pad arrangement of FIG. 3B thus becomes universally applicable. Due to the uncomplicated manner, in which the universal contact pad pattern can be expanded to higher numbers of pads, the disadvantage by converting from wire bond to bump interconnection (discussed in FIGS. 1B and 2B in conventional technology) can easily be overcome.

Another embodiment of the invention is an apparatus comprising an insulating substrate, which has first and second surfaces and a plurality of metal-filled vias extending from the first to the second surface. The first substrate surface has contact pads of about the same size and the second surface has contact pads of about the same size. Further, a selected plurality of the pads is connected to one of the vias, respectively. The contact pads on the first surface are equidistantly arrayed in parallel rows, the pads in each row interconnected by conducting traces and positioned so that the corresponding pad of each following row is located at a predetermined angle relative to the respective pad of the preceding row, said angle selected for minimizing the pitch of said traces, center-to-center, and maximizing the pad density.

In the preferred embodiment, the apparatus is suitable for an integrated circuit assembly; consequently, the pads on the first substrate surface are operable as signal input/output terminals by being arranged in number and position to match the corresponding signal input/output pads of the integrated circuit. In addition, the apparatus comprises a plurality of additional contact pads for power and ground connections of the integrated circuit.

Furthermore, in this preferred embodiment, the contact pads on said second substrate surface have a size, which is different from the size of the contact pads on the first surface; these contact pads are arranged in number and position to match the attachment pads of an external part.

Preferred materials for the substrate include insulators such as epoxy, polyimide, FR-4, FR-5, glass fiber-enforced polymers, and related compound. The contact pads on the first and the second substrate surface are preferably made of copper or a copper alloy, frequently with a thin gold surface layer. Such pads are equally suitable for attachment of gold bumps and reflow metal balls such as tin or tin alloys.

These substrate and contact pad materials are also suitable for scaling the pitch of the connecting traces according to the number and the position of the integrated circuit pads.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the invention covers not only substrates for integrated circuits made of silicon, silicon germanium, gallium arsenide, or any other semiconductor material, including multi-chip assemblies, but also substrates used for assembling other electronic parts on larger boards.

It is therefore intended that the appended claims encompass any such modifications or embodiments.

1. A semiconductor device comprising:
an semiconductor chip with a length, a width, and a pad pattern; and
a substrate including insulating material, having a surface and a plurality of metal pads on said surface interconnected by parallel conductive traces;
said pads arranged in repetitive order of patterned rows and blocks; and
only one block of the repetitive blocks matching the length of the semiconductor chip and mirroring the pad pattern of the semiconductor chip.

2. The semiconductor device according to claim 1 wherein said arrangement is a rectangular array.

3-17. (canceled)
